(19) United States
(12) Patent Application Publication
(10) Pub. No.: US 2025/0141414 A1
(43) Pub. Date: May 1, 2025

(54) POWER AMPLIFIER WITH PROTECTION LOOP

(71) Applicant: Qorvo US, Inc., Greensboro, NC (US)

(72) Inventors: Baker Scott, San Jose, CA (US); George Maxim, Saratoga, CA (US); Chong Woo, Fremont, CA (US); Stephen Franck, Felton, CA (US)

(21) Appl. No.: 18/835,801

(22) PCT Filed: Feb. 23, 2023
(86) PCT No.: PCT/US2023/013683

§ 371 Date: Aug. 5, 2024

Related U.S. Application Data
(60) Provisional application No. 63/313,072, filed on Feb. 23, 2022.

(51) Int. Cl. H03F 3/24; H03F 1/52

(52) U.S. Cl. CPC H03F 3/245; H03F 1/52; H03F 2200/426; H03F 2200/451

(57) ABSTRACT

A power amplifier includes an over-current protection loop and/or an over-voltage protection loop to assist in preventing operation outside a safe operating zone. In particular, a trigger threshold for the protection loop may dynamically change as a function of another parameter associated with the transmission. Exemplary parameters include, but are not necessarily limited to: supply voltage, temperature, frequency, modulation, voltage standing wave ratio (VSWR), or combinations thereof. In still further exemplary aspects, the over-voltage protection loop may operate independently of the over-current protection current loop, or the over-voltage protection loop contribute to an over-current protection signal.

### PRIORITY CLAIM

The present application claims priority to U.S. Patent Application Ser. No. 63/313,072, filed on Feb. 23, 2022, and entitled “5G POWER AMPLIFIER WITH DYNAMIC THRESHOLD ADJUSTMENT FOR BOTH OVER-CURRENT AND OVER-VOLTAGE PROTECTION LOOPS FOR AMR,” the contents of which is incorporated herein by reference in its entirety.

### FIELD OF THE DISCLOSURE

The technology of the disclosure relates generally to a power amplifier circuit that operates in rugged conditions such as over-current situations and/or over-voltage situations.

### BACKGROUND

Mobile communication devices have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

Most mobile communication devices include a transmission chain, including a power amplifier, power amplifier array, or series of staged power amplifiers that boost signals before transmission through an antenna. While the power amplifiers used in such situations are designed to operate over a wide range of conditions, end users, either innocently or by design, frequently find ways to stress the power amplifiers beyond the intended operational range. When a power amplifier is subjected to conditions beyond its design tolerances, the power amplifier may fail, resulting in a failure or diminished functionality of the transmission chain with a corresponding loss of functionality for the mobile communication device.

Recognizing this possibility, some manufacturers of mobile communication devices have announced vigorous requirements for power amplifiers. Meeting these vigorous requirements presents opportunities for new solutions.

### SUMMARY

Aspects of the disclosure relate to a power amplifier with a protective loop. Specifically, exemplary aspects contemplate providing an over-current protection loop and/or an over-voltage protection loop to assist in preventing operation outside a safe operating zone. In a further exemplary aspect, a trigger threshold for the protection loop may dynamically change as a function of some other parameter associated with the transmission. Exemplary parameters include, but are not necessarily limited to: supply voltage, temperature, frequency, signal bandwidth, modulation, voltage standing wave ratio (VSWR), or combinations thereof. In still further exemplary aspects, the over-voltage protection loop may operate independently of the over-current protection current loop, or the over-voltage protection loop contributes to an over-current protection signal. Using such over-current and/or over-voltage protection loops reduces the chance that the power amplifier will operate outside a safe operating area of the power amplifier, thereby satisfying the testing criteria of the mobile communication device manufacturers and likely extending the life cycle of the power amplifier.

In one aspect, a power amplifier circuit is disclosed.

In another aspect, a power amplifier system is disclosed.

In another aspect, a power amplifier circuit is disclosed.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 is a schematic diagram of an exemplary radio frequency (RF) front-end circuit configured according to an embodiment of the present disclosure;

FIG. 2 is a schematic diagram of a wireless device, including a number of RF front-end circuits of FIG. 1;

FIG. 3 is a current versus voltage diagram showing a safe region of operation and how excess current and/or excess voltage may push operation of a power amplifier outside the safe region of operation;

FIG. 4 is a time versus voltage standing wave ratio diagram showing the results of unprotected over-current conditions;

FIG. 5 is a block diagram of a conventional power amplifier circuit having overcurrent and overvoltage detector circuits that may cause ringing or fail to limit the overcurrent/overvoltage condition adequately;

FIG. 6 is a block diagram of a power amplifier circuit having independent overcurrent and overvoltage detector circuits where an overcurrent protection (OCP) signal from the overcurrent detector circuit is also provided to a driver stage of a power amplifier to control an input signal to an output stage of the power amplifier using a regulator circuit;

FIG. 7 is a block diagram of a power amplifier circuit having overcurrent and overvoltage detector circuits where an OCP signal from the overcurrent detector circuit is also provided to a driver stage of a power amplifier to control an input signal to an output stage of the power amplifier and where the overvoltage detection circuit provides a signal that is summed with the OCP signal;

FIG. 8 is a block diagram of a power amplifier circuit having overcurrent and overvoltage detector circuits where an OCP signal from the overcurrent detector circuit is also provided to a driver stage of a power amplifier to control an input signal to an output stage of the power amplifier using a second bias circuit;

FIG. 9 is a block diagram of a power amplifier circuit having overcurrent and overvoltage detector circuits where an OCP signal from the overcurrent detector circuit is also provided to a clamp to control an input signal to an output stage of the power amplifier;

FIG. 10 is a block diagram of a power amplifier circuit having overcurrent and overvoltage detector circuits where an OCP signal from the overcurrent detector circuit is provided not just to a regulator circuit but also to a bias circuit;

FIG. 11 is a current versus voltage diagram similar to FIG. 3 but showing how a threshold may dynamically change to assist in keeping operation in a safe region of operation;

FIG. 12 is a block diagram of a power amplifier circuit having an OCP loop with a dynamic threshold based on one or more operating parameters;

FIG. 13 is a block diagram of a power amplifier circuit having an OCP loop with a dynamic threshold based on one or more operating parameters, which may be locally sensed or provided from a remote source such as a baseband processor;

FIG. 14 is a block diagram of a power amplifier circuit having an OCP loop that works with an overvoltage protection (OVP) loop, each loop having a dynamic threshold;

FIG. 15 is a block diagram of a power amplifier circuit where the OVP loop has its dynamic threshold set in part by the OCP loop;

FIG. 16 is a block diagram of a power amplifier circuit having multiple OVP loops working with different stages of the power amplifier; and

FIG. 17 is a block diagram of a power amplifier circuit having a variety of protection devices and protection loops to assist in operation in rugged conditions.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element, or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects of the disclosure relate to a power amplifier with a protective loop. Specifically, exemplary aspects contemplate providing an over-current protection loop and/or an over-voltage protection loop to assist in preventing operation outside a safe operating zone. In a further exemplary aspect, a trigger threshold for the protection loop may dynamically change as a function of some other parameter associated with the transmission. Exemplary parameters include, but are not necessarily limited to: supply voltage, temperature, frequency, signal bandwidth, modulation, voltage standing wave ratio (VSWR), or combinations thereof. In still further exemplary aspects, the over-voltage protection loop may operate independently of the over-current protection current loop, or the over-voltage protection loop contributes to an over-current protection signal. Using such over-current and/or over-voltage protection loops reduces the chance that the power amplifier will operate outside a safe operating area of the power amplifier, thereby satisfying the testing criteria of the mobile communication device manufacturers and likely extending the life cycle of the power amplifier.

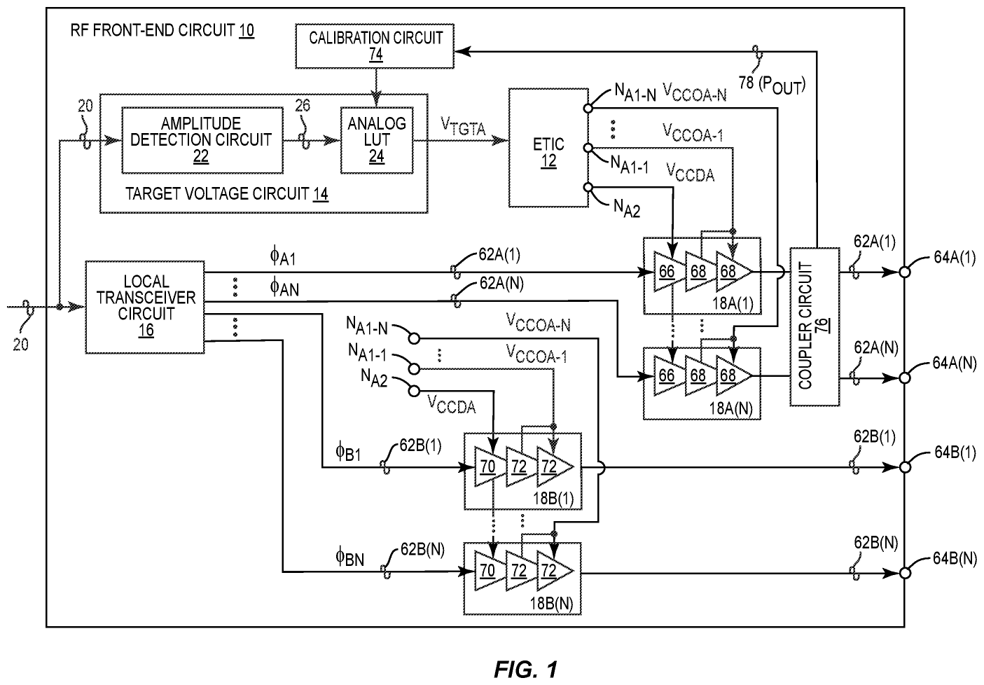

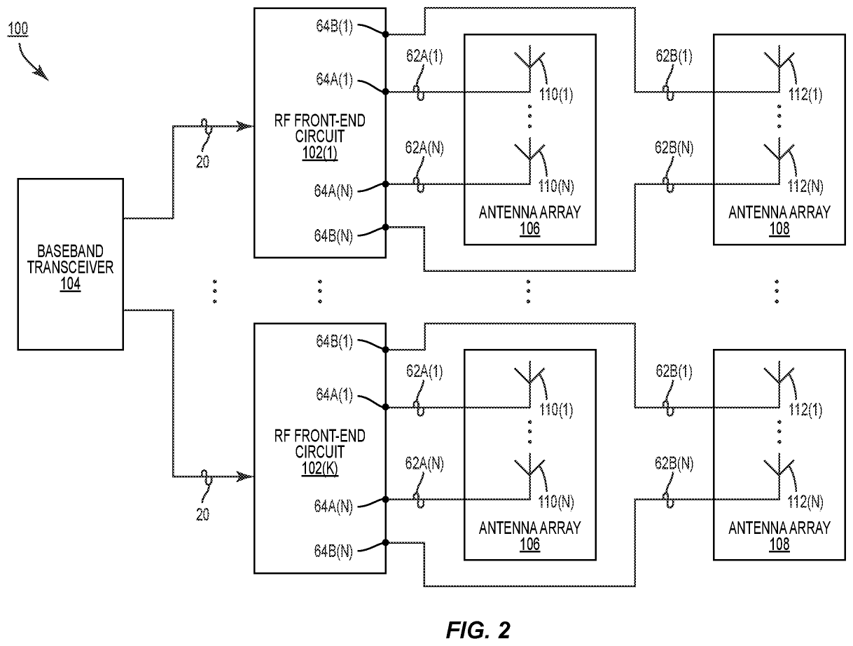

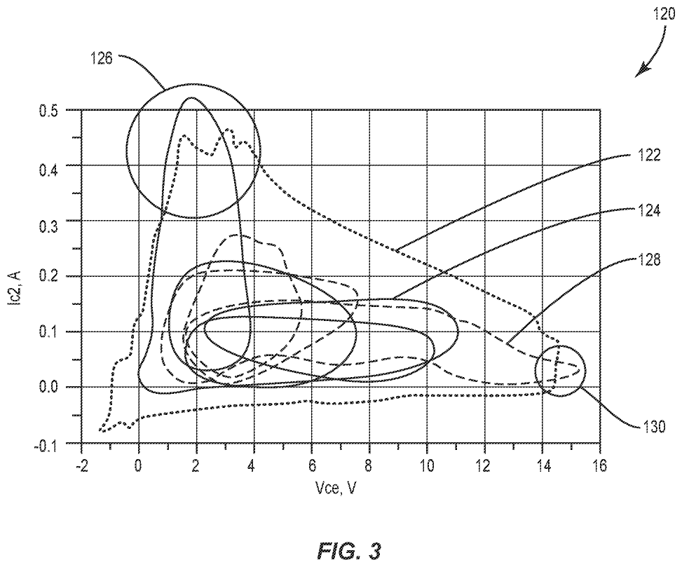

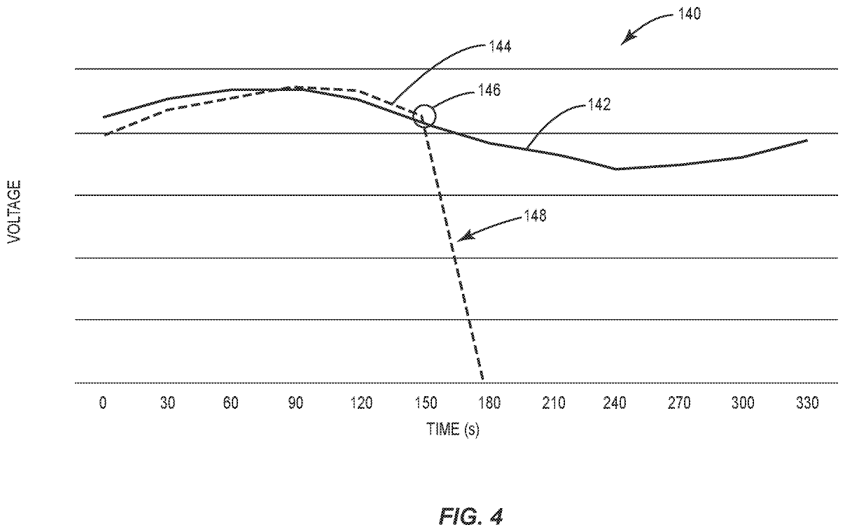

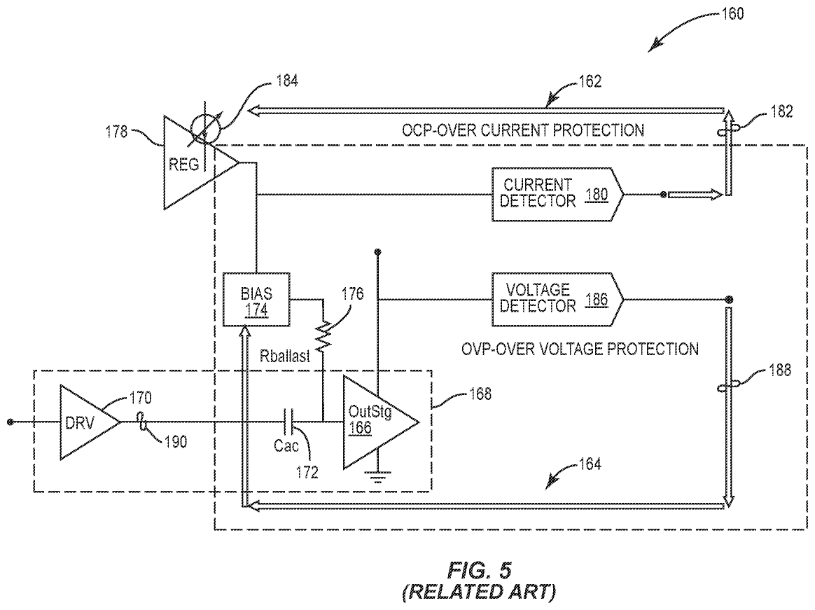

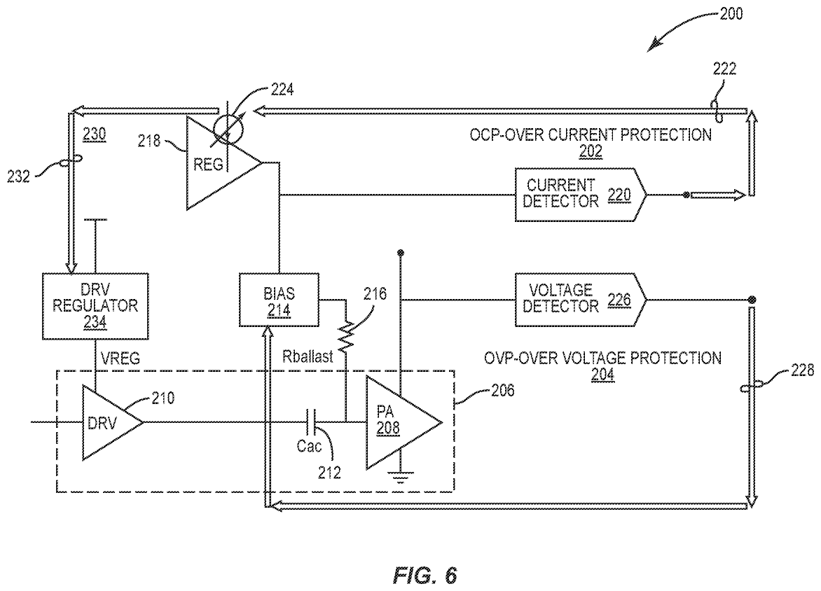

Before addressing particular aspects of the present disclosure, a brief discussion of the context is provided. Specifically, FIG. 1 illustrates a radio frequency (RF) front-end circuit that includes power amplifiers that may benefit from the protection loops of the present disclosure. FIG. 2 illustrates a wireless device that may include an RF front-end circuit that may include the power amplifiers of FIG. 1. FIG. 3 provides a graphical illustration of a safe region of operation with possible instances of operation that exit the safe region of operation, while FIG. 4 illustrates graphically the possible ramifications of exiting the safe region of operation. FIG. 5 provides a description of conventional solutions and a discussion of their shortcomings. Discussion of exemplary aspects of the present disclosure begins below with reference to FIG. 6.

FIG. 1 is a schematic diagram of an exemplary RF front-end circuit 10 configured according to an aspect of the present disclosure. The RF front-end circuit 10 may be self-contained in a system-on-chip (SoC) or system-in-package (SiP), as an example, to provide all essential functions of an RF front-end module (FEM). Alternatively, different portions of the RF front-end circuit 10 may be provided on different dies. In some embodiments, the different dies may be made from different materials (e.g., GaAs, GaAn, Si, SiG, SiN, or the like) and/or may be different technologies (e.g., bipolar junction transistors (BJTs), heterojunction transistors, field effect transistors (FETs), complementary metal oxide semiconductor (CMOS) FETs, or the like). As illustrated, the RF front-end circuit 10 is configured to include an envelope tracking integrated circuit (ETIC) 12, a target voltage circuit 14, a local transceiver circuit 16, and a number of power amplifiers 18A(1)-18A(N). The RF front-end circuit 10 may also include a number of second power amplifiers 18B(1)-18B(N). The ETIC 12 may be replaced with an average power tracking (APT) circuit (not shown).

The ETIC 12 is configured to generate a number of first ET voltages V_{CCOA-1}-V_{CCOA-N} at a number of first output nodes N_{A1-1}-N_{A1-N}, respectively. The ETIC 12 is also configured to generate a second ET voltage V_{CCDA} at a second output node N_{A2}. The ETIC 12 generates both the first ET voltages V_{CCOA-1}-V_{CCOA-N} and the second ET voltage V_{CCDA} based on a time-variant ET target voltage V_{TGTA}. For a detailed description of specific embodiments of the ETIC 12 that generate the first ET voltages V_{CCOA-1}-V_{CCOA-N} and the second ET voltage V_{CCDA} based on the time-variant ET target voltage V_{TGTA}, please refer to U.S. patent application Ser. No. 17/142,507, entitled “ENVELOPE TRACKING POWER MANAGEMENT APPARATUS INCORPORATING MULTIPLE POWER AMPLIFIERS.”

The target voltage circuit 14 is configured to generate the time-variant ET target voltage V_{TGTA} based on an input signal 20, which can be a modulated carrier signal at a radio frequency (RF), a millimeter wave (mmWave) frequency, intermediate frequency (IF), In-phase/Quadrature (I/Q) baseband frequency. In a non-limiting example, the target voltage circuit 14 includes an amplitude detection circuit 22 and an analog look-up table (LUT) 24. The amplitude detection circuit 22 is configured to detect a number of time-variant amplitudes 26 of the input signal 20, and the analog LUT 24 is configured to generate the time-variant ET target voltage V_{TGTA} based on the time-variant amplitudes 26.

The local transceiver circuit 16 may be coupled to a baseband transceiver circuit (not shown), which is separated from the RF front-end circuit 10 by a conductive distance that can stretch to several centimeters. The baseband transceiver circuit may provide the input signal 20 to the local transceiver circuit 16 in IF to help reduce distortion over the conductive distance. In this regard, in a non-limiting example, the baseband transceiver circuit can upconvert a baseband frequency signal to the IF to form the input signal 20. The local transceiver circuit 16 is configured to generate a number of RF signals 62A(1)-62A(N) and a number of second RF signals 62B(1)-62B(N) in an RF frequency (a.k.a. carrier frequency) higher than the IF based on the input signal 20.

Each of the power amplifiers 18A(1)-18A(N) is coupled to a respective one of a number of antenna ports 64A(1)-64A(N) and configured to amplify a respective one of the RF signals 62A(1)-62A(N) based on a respective one of the first ET voltages V_{CCOA-1}-V_{CCOA-N} as well as the second ET voltage V_{CCDA}. Each of the second power amplifiers 18B(1)-18B(N) is coupled to a respective one of a number of second antenna ports 64B(1)-64B(N) and configured to amplify a respective one of the second RF signals 62B(1)-62B(N) based on a respective one of the first ET voltages V_{CCOA-1}-V_{CCOA-N} as well as the second ET voltage V_{CCDA}.

The antenna ports 64A(1)-64A(N) and the second antenna ports 64B(1)-64B(N) may each be coupled to a respective antenna (not shown) for radiating a respective one of the RF signals 62A(1)-62A(N) and the second RF signals 62B(1)-62B(N). The local transceiver circuit 16 may be configured to generate the RF signals 62A(1)-62A(N) in association with a number of phase offsets ϕ_{A1}-ϕ_{AN}, respectively, to provide required phase coherency among the RF signals 62A(1)-62A(N) such that the RF signals 62A(1)-62A(N) can be radiated by respective antennas via RF beamforming. Similarly, the local transceiver circuit 16 may also be configured to generate the second RF signals 62B(1)-62B(N) in association with a number of second phase offsets ϕ_{B1}-ϕ_{BN}, respectively, to provide required phase coherency among the second RF signals 62B(1)-62B(N) such that the second RF signals 62B(1)-62B(N) can be radiated by respective antennas via RF beamforming. Notably, each of RF signals 62A(1)-62A(N) may be identical to a respective one of the second RF signals 62B(1)-62B(N) (e.g., having the same content and encoding). As such, the RF signals 62A(1)-62A(N) and the second RF signals 62B(1)-62B(N) may be simultaneously radiated in different polarizations (e.g., horizontal and vertical polarizations).

In a non-limiting example, each of the power amplifiers 18A(1)-18A(N) is a multi-stage power amplifier that includes a driver stage amplifier 66 and one or more output stage amplifiers 68. The driver stage amplifier 66 in each of the power amplifiers 18A(1)-18A(N) is configured to amplify a respective one of the RF signals 62A(1)-62A(N) based on the second ET voltage V_{CCDA}. The output stage amplifiers 68 in each of the power amplifiers 18A(1)-18A(N) is coupled between the driver stage amplifier 66 and a respective one of the antenna ports 64A(1)-64A(N). Accordingly, the output stage amplifiers 68 in each of the power amplifiers 18A(1)-18A(N) are configured to further amplify the respective one of the RF signals 62A(1)-62A(N) based on a respective one of the first ET voltages V_{CCOA-1}-V_{CCOA-N}.

Likewise, each of the second power amplifiers 18B(1)-18B(N) is a multi-stage power amplifier that includes a second driver stage amplifier 70 and one or more second output stage amplifiers 72. The second driver stage amplifier 70 in each of the second power amplifiers 18B(1)-18B(N) is configured to amplify a respective one of the second RF signals 62B(1)-62B(N) based on the second ET voltage V_{CCDA}. The second output stage amplifiers 72 in each of the second power amplifiers 18B(1)-18B(N) is coupled between the second driver stage amplifier 70 and a respective one of the second antenna ports 64B(1)-64B(N). Accordingly, the second output stage amplifiers 72 in each of the second power amplifiers 18B(1)-18B(N) are configured to further amplify the respective one of the second RF signals 62B(1)-62B(N) based on a respective one of the first ET voltages V_{CCOA-1}-V_{CCOA-N}.

The RF front-end circuit 10 may include a calibration circuit 74 and a coupling circuit 76. The coupling circuit 76 may be provided between the power amplifiers 18A(1)-18A(N) and the antenna ports 64A(1)-64A(N) and/or between the second power amplifiers 18B(1)-18B(N) and the second antenna ports 64B(1)-64B(N). The coupling circuit 76 may be configured to provide a feedback signal 78 indicating an output power P_{OUT} of any of the power amplifiers 18A(1)-18A(N) and/or any of the second power amplifiers 18B(1)-18B(N). Accordingly, the calibration circuit 74 may be configured to calibrate the analog LUT 24 based on the feedback signal 78. For a detailed description of specific embodiments of the calibration circuit 74, please refer to U.S. patent application Ser. No. 17/163,685, entitled “APPARATUS AND METHOD FOR CALIBRATING AN ENVELOPE TRACKING LOOK-UP TABLE.”

FIG. 2 is a schematic diagram of a wireless device 100 that includes a number of RF front-end circuits 102(1)-102(K), which can be the RF front-end circuit 10 of FIG. 1.

The wireless device 100 includes a baseband transceiver 104 that is separated from any of the RF front-end circuits 102(1)-102(K). The baseband transceiver 104 is configured the generate the input signal 20.

Each RF front-end circuit 102(1)-102(K) is coupled to a first antenna array 106 and a second antenna array 108. The first antenna array 106 includes a number of first antennas 110(1)-110(N), each coupled to a respective one of the antenna ports 64A(1)-64A(N) and configured to radiate a respective one of the RF signals 62A(1)-62A(N) in a first polarization (e.g., horizontal polarization). The second antenna array 108 includes a number of second antennas 112(1)-112(N), each coupled to a respective one of the second antenna ports 64B(1)-64B(N) and configured to radiate a respective one of the second RF signals 62B(1)-62B(N) in a second polarization (e.g., vertical polarization).

The RF front-end circuits 102(1)-102(K) may be disposed in different locations in the wireless device 100 to help enhance RF performance and improve user experience. For example, some of the RF front-end circuits 102(1)-102(K) may be provided on a top edge of the wireless device 100, while some of the ET RF front-end circuits 102(1)-102(K) are provided on a bottom edge of the wireless device 100.

While the above discussion focuses on an RF front-end circuit 10 suitable for use in Fifth Generation (5G) cellular networks, the present disclosure is not so limited, and the present disclosure may be implemented in 3G, 4G, 5G networks, or the like. Of interest is the operation of the power amplifiers 18A(1)-18A(N) and power amplifiers 18B(1)-18B(N) and, more particularly, the output stage amplifiers 68 and 72. It should be appreciated that while the power amplifiers are designed to be robust and operate over a wide spectrum of operating conditions, the power amplifiers are the product of design compromises, and, as a result, the power amplifiers may have an optimal operating region, a region where it is safe for the power amplifier to operate, and regions where the power amplifier may fail.

FIG. 3 illustrates a voltage (Vce) versus current (Ic2) graph 120 with a safe region of operation (illustrated in FIG. 3 by curve 122, although subsequently referred to as safe area of operation 122). As current fluctuates, as illustrated by line 124, the current may exit the safe area of operation 122 (sometimes referred to as safe-operating-area (SOA)) as denoted by region 126. Likewise, as voltage fluctuates, as illustrated by line 128, the voltage may exit the safe area of operation 122, as denoted by region 130. Region 126 may be an overcurrent failure, and region 130 may be an overvoltage failure.

Again, while the power amplifiers are designed to be robust and continue operation at a wide range of operating conditions, it is possible to push the power amplifiers outside the safe region of operation and cause a failure. FIG. 4 provides a voltage versus time graph 140 where two amplifiers operate. A first amplifier, denoted by line 142, stays within a safe region of operation and continues to function. A second amplifier, denoted by line 144, has an overcurrent condition at time 146 and fails. After a sharp decline 148, operation does not continue for the second amplifier. Such failure can lead to performance degradation up to and including complete loss of functionality (e.g., so-called “bricking” the device). Perhaps cognizant that such failures may lead to an erosion of consumer confidence, manufacturers subject power amplifiers to myriad tests to verify that the power amplifiers are sufficiently rugged, including extreme Voltage Standing Wave Ratios (VSWR) (e.g., 10:1), large battery voltage levels (VBat) and Vcc voltages (e.g., +0.5 V higher than normal). Even without the need to satisfy such manufacturer ruggedness tests, there is a desire to provide power amplifiers that can withstand a variety of operating conditions with suitable worst-case margins.

FIG. 5 provides a block diagram of a power amplifier circuit 160 that employs conventional protection schemes to assist in meeting ruggedness tests. In particular, the power amplifier circuit 160 includes an overcurrent protection (OCP) loop 162 and an overvoltage (OVP) loop 164 that assist in preventing overcurrent and overvoltage conditions for an output stage 166 of a power amplifier 168. While not shown, the power amplifier 168 may be a multi-stage power amplifier, as illustrated in FIG. 1 for power amplifier 18A. Additionally, the power amplifier 168 may have a driver amplifier stage 170, which may (or may not) be considered part of the power amplifier 168. The driver amplifier stage 170 may be separated from the output stage 166 by a capacitor 172 that blocks direct current (DC) but passes alternating current (AC). The output stage 168 receives a bias signal from a bias circuit 174 through a resistor 176. The bias circuit 174 may be regulated by a bias regulator circuit 178.

With continued reference to FIG. 5, a current detector circuit 180 may sense a current provided from the bias regulator circuit 178 to the bias circuit 174 with the understanding that this detected current is a reasonable proxy for the current provided to the bias circuit 174 and thus also a reasonable proxy for the current output by the output stage 166. The current detector circuit 180 also provides an OCP signal 182 to an adjustable current source 184 associated with the bias regulator circuit 178 when a current level above a predetermined threshold is detected.

It should be appreciated that traditional GaAs power amplifiers have difficulty in implementing OCP loops compared with the voltages required by HBT devices for proper operation. That is, for example, direct Vcc collector current sensing is generally not advisable as it negatively impacts the operation of the power amplifier. On the base side, there is generally insufficient voltage headroom at the minimum supply voltage to include an additional HBT device for control. Furthermore, GaAs HBT processes cannot efficiently implement digital control circuits and adjustability for the protection loops.

With continued reference to FIG. 5, a voltage detection circuit 186 detects a voltage level associated with the output stage 166 and provides an OVP signal 188 to the bias circuit 174 when the detected voltage level exceeds a predefined threshold.

While the current detector circuit 180 and the voltage detection circuit 186 help reduce or eliminate instances where the current and/or voltage exceed design tolerances, at least three limitations have been observed. First, the OCP signal 182 and the OVP signal 188 may operate against each other, making adjustments in the bias regulator circuit 178 that cancel adjustments made in the bias circuit 174 or vice versa. As each circuit compensates for the other, the changes may induce a ringing in the output stage 166, where the ringing may negatively impact performance. Second, while the current and voltage limitations may be in place, the driver amplifier stage 170 may continue to drive the signal 190 at large values, which, in turn, may cause the output stage 166 to exit the safe region of operation and result in failure or damage to the output stage. Third, many OVP circuits are implemented with diode stacks, which typically require relatively large areas on the die since they need to hold the limiting current. Likewise, diode stacks provide just a static protection level that may not be reflective of the contours of the safe operating area.

Exemplary aspects of the present disclosure provide a variety of tools with which to manage operation of the power amplifier circuit. Specifically contemplated aspects include providing additional control to a driver amplifier stage, either through control of a bias or regulator circuit of the driver amplifier stage or through a clamp circuit on the connection between the driver amplifier stage and the output stage (e.g., thereby clamping signal 190). A further tool is linking the OVP signal to the OCP signal such that ringing is reduced or minimized. Still, another tool is dynamic adjustment of an overvoltage condition based on the presence or absence of an overcurrent situation. That is, when an overcurrent situation occurs, it may take less voltage to induce failure. Accordingly, during overcurrent situations, the threshold for the OVP signal may be lowered. Still another aspect of the present disclosure contemplates

It should be appreciated that while illustrated aspects focus on a GaAs BJT implementation, the present disclosure is not so limited. In exemplary aspects, the concepts of the present disclosure may be applied to amplifiers formed from GaAs, GaAN, SiGe, Si, or the like. Likewise, the amplifiers may use transistors that are BJTs, HBTs, FETs, or the like. In a particularly contemplated aspect, the power amplifier circuit may serve a hybrid RF path with a CMOS driver and a GaAs (either BJT or HBT) output stage. It should be appreciated that the concepts disclosed herein are applicable for any power amplifier configuration, including but not limited to single-ended, differential, pseudo-differential, quadrature, Doherty, out-phasing, and the like. Further, while the description of FIGS. 1 and 2 reflect a 5G implementation, it should be appreciated that the concepts disclosed herein are applicable to 3G and/or 4G use cases, and digital control circuitry (described in greater detail below) may allow switching between different protection limits when switching between the 3G, 4G, and 5G use cases when a single-mode transmission chain is used.

As noted above, direct current sensing may be inappropriate. Accordingly, in some implementations, an indirect current sensing in the base of the device may be appropriate. Likewise, it is advantageous for an OCP loop to have devices with much lower control voltage levels (e.g., Vgs<<Vbe) and also have digital circuits that can provide control and adjustability of the OCP loop settings. Accordingly, biasing the collector of the emitter follower from a dedicated regulator provides a path to sense and limit the collector current, which in turn will limit the base current of the output device. Such regulators may be implemented in silicon processes (e.g., CMOS or BiCMOS). A digital-to-analog converter (DAC) can be used to adjust and program the current limiting value. However, such an arrangement is not strictly required for all aspects of the present disclosure, but such will be used to illustrate an exemplary aspect of the present disclosure.

In this regard, FIG. 6 illustrates a power amplifier circuit 200 that includes an OCP loop 202 and an OVP loop 204 to assist in protecting a power amplifier 206 that includes an output stage 208. While not shown, the power amplifier 206 may be a multi-stage power amplifier, as illustrated in FIG. 1. Additionally, the power amplifier 206 may have a driver amplifier stage 210, which may (or may not) be considered part of the power amplifier 206. The driver amplifier stage 210 may be separated from the output stage 208 by a capacitor 212 that blocks direct current (DC) but passes alternating current (AC). The output stage 208 receives a bias signal from a bias circuit 214 through a resistor 216. The bias circuit 214 may be regulated by a bias regulator circuit 218.

With continued reference to FIG. 6, a current detector circuit 220 may sense a current provided from the bias regulator circuit 218 to the bias circuit 214 with the understanding that this detected current is a reasonable proxy for the current provided to the bias circuit 214 and thus also a reasonable proxy for the current output by the output stage 208. The current detector circuit 220 also provides an OCP signal 222 to an adjustable current source 224 associated with the bias regulator circuit 218 when a current level above a predetermined threshold is detected. Note that this threshold may be dynamic, as described below.

With continued reference to FIG. 6, a voltage detection circuit 226 detects a voltage level associated with the output stage 208 and provides an OVP signal 228 to the bias circuit 214 when the detected voltage level exceeds a predefined threshold. Note that this threshold may be dynamic, as defined below.

To address one of the limitations of the system of FIG. 5, an auxiliary OCP loop 230 is added. The auxiliary OCP loop 230 provides a second OCP protection signal 232 in such a manner as to help limit the driver amplifier stage 210. As illustrated in FIG. 6, the second OCP signal 232 is provided to a driver regulator circuit 234. The driver regulator circuit 234 regulates the driver amplifier stage 210, much like the regulator circuit 218 regulates the output stage 208. Note that in an exemplary aspect, the regulator circuit 218 and the driver regulator circuit 234 are implemented in a CMOS die, while the bias circuit 214, output stage 208, and voltage detector circuits 220, 226 are all implemented in a GaAs die. Further note that where the OCP loop 202 and the OVP loop 204 operate independently, the timing of the OCP loop 202 may be relatively fast compared to the timing of the OVP loop 204, such that quick changes are made through OCP loop 202, and gradual changes are made through the OVP loop 204. By having this different timing, the likelihood of ringing is reduced.

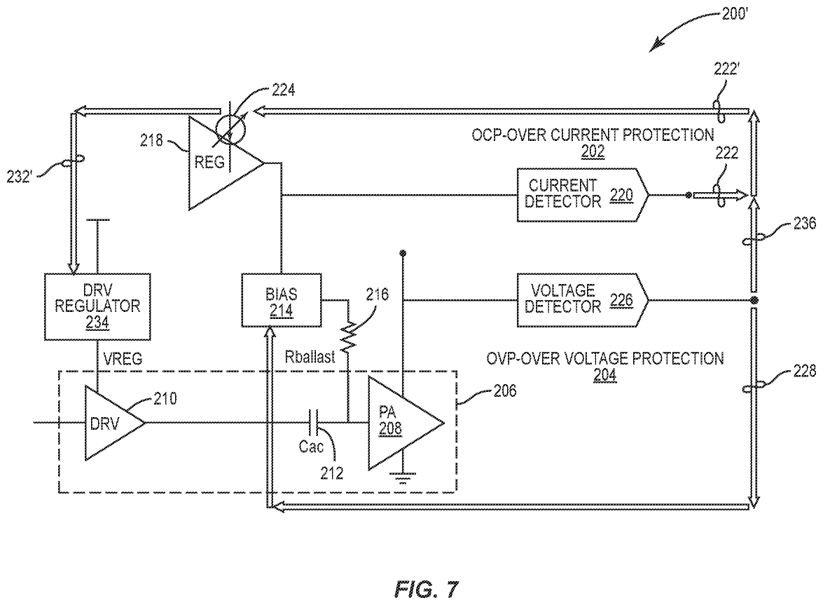

To further reduce the likelihood of ringing, a power amplifier circuit 200′ takes the additional step of linking via signal 236, the OVP signal 228, to the OCP signal 222, as illustrated in FIG. 7. In most other respects, the power amplifier circuit 200′ is nearly identical to the power amplifier circuit 200 of FIG. 6. The net result of adding the OVP signal 236 to the OCP signal 222 is the resulting signal 222′ which activates the regulator circuit 218 earlier than just those situations where there is high current. In an exemplary aspect, the OVP signal 236 alone exceeds the threshold sufficient to trigger OCP measures (e.g., limiting the regulator circuit 218). The combined signal 222′ also impacts signal 232′, which controls the driver regulator circuit 234.

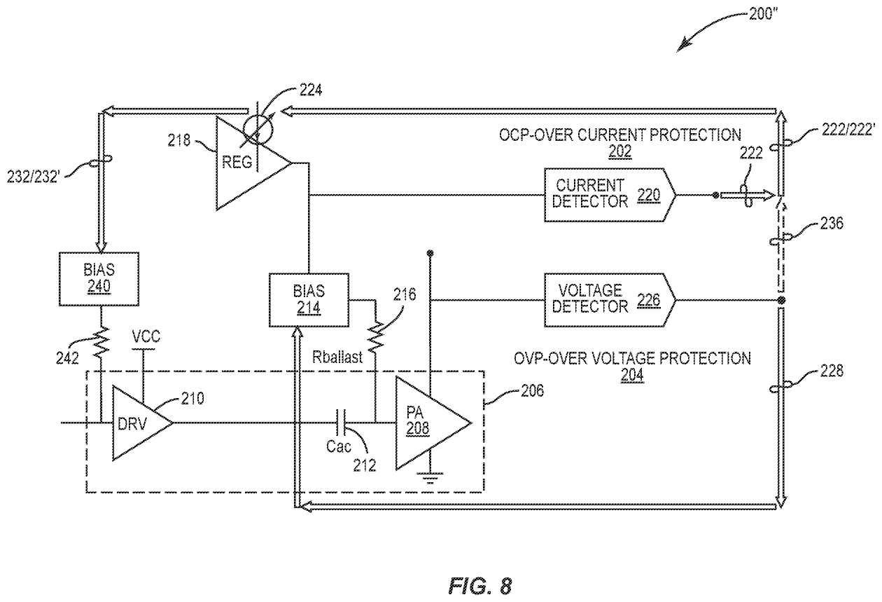

Instead of controlling a driver regulator circuit 234, as shown in FIG. 6 or 7, the second OCP signal 232 or 232′ may instead control a driver bias circuit 240, which biases the driver amplifier stage 210 through a resistor 242, as shown in the power amplifier circuit 200″ in FIG. 8. It should be appreciated that the power amplifier circuit 200″ may have linked loops 202 and 204 as in FIG. 7 or independent loops 202 and 204 as in FIG. 6.

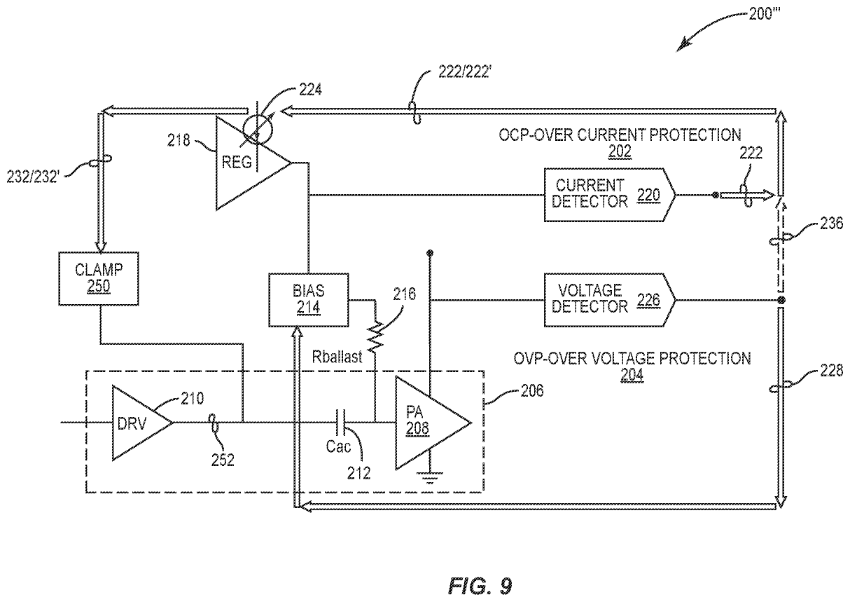

Instead of controlling a driver regulator circuit 234 or a bias circuit 240, as shown in FIGS. 6-8, the second OCP signal 232 or 232′ may instead control a clamp 250, which provides a limit on the output signal 252 of the driver amplifier stage 210 as shown in the power amplifier circuit 200″′ in FIG. 9. It should be appreciated that the power amplifier circuit 200″ may have linked loops 202 and 204, as in FIG. 7, or independent loops 202 and 204, as in FIG. 6.

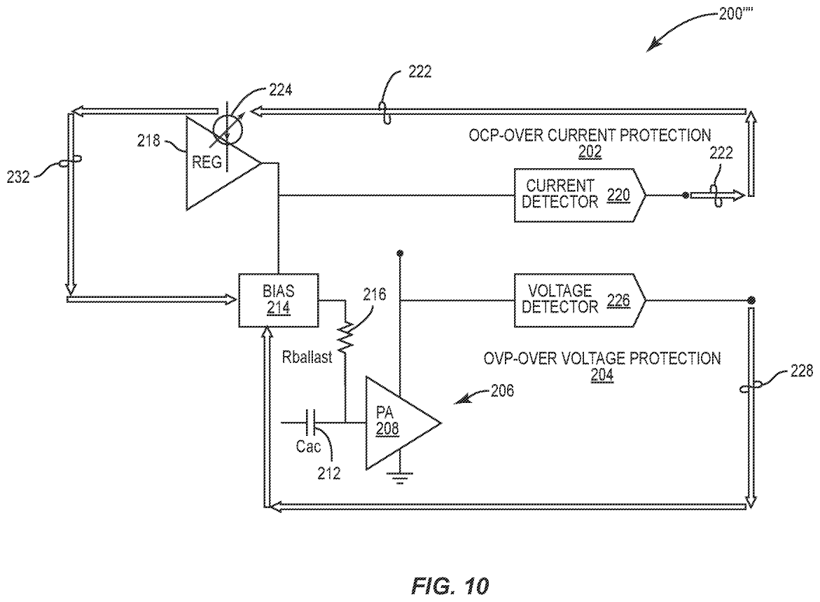

Instead of controlling the driver amplifier stage 210, it may be possible to provide additional control to the bias circuit 214, as shown in the power amplifier circuit 200″ in FIG. 10. Specifically, the signal 232 lowers the bias voltage through the bias circuit 214. Since the bias circuit 214 receives signals from both the OCP loop 202 and the OVP loop 204, the OCP loop 204 does not have to be linked to the OCP loop 202 (although it can be).

As alluded to above, the present disclosure may include the ability to set threshold levels dynamically based on other operating parameters.

Exemplary operating parameters may include supply voltages (Vcc), temperature, frequency, power levels, modulation schemes, VSWR, or the like and/or combinations of these.

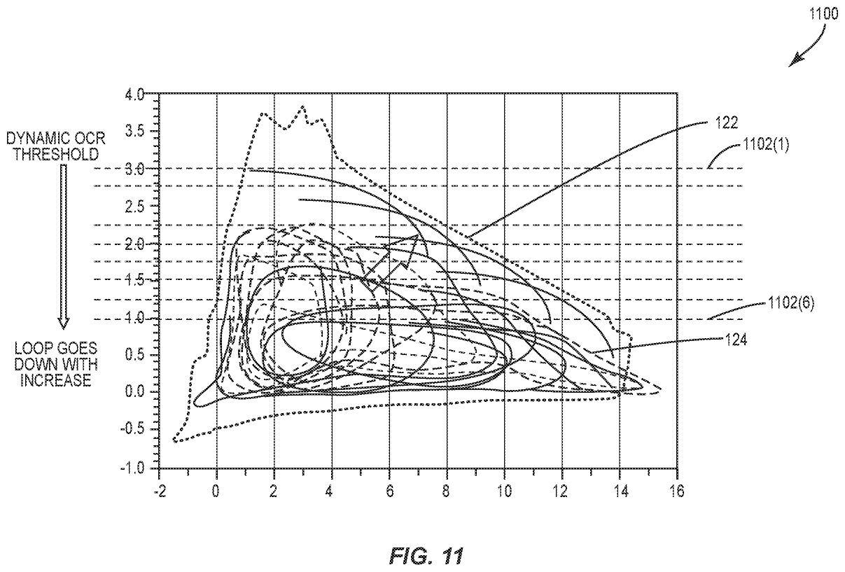

In this regard, FIG. 11 provides a graph 1100 similar to graph 120 of FIG. 3 with current plotted against voltage and a safe area of operation 122 shown. As Vcc increases, the threshold 1102(1)-1102(V) decreases, increasing the likelihood that the trajectory 124 stays inside the safe area of operation 122.

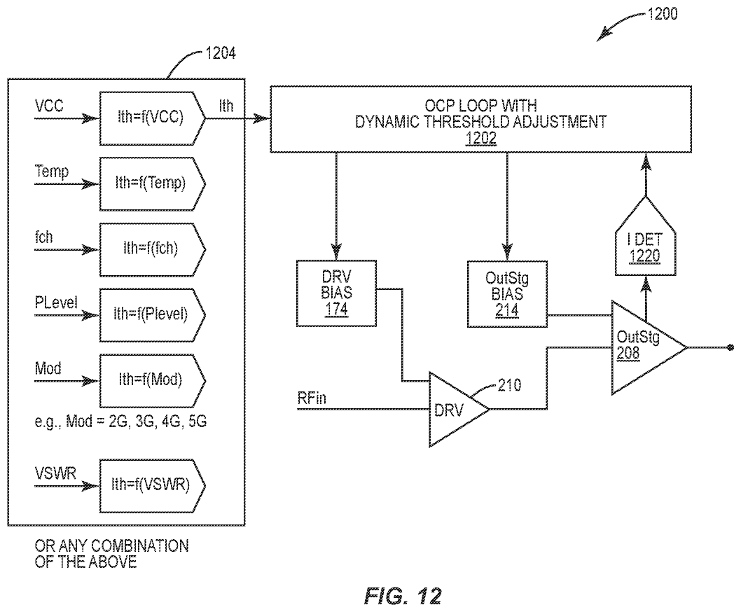

FIG. 12 illustrates a power amplifier circuit 1200 with an OCP loop 1202 that uses a current detector 1220 to generate the OCP signal. The circuitry of the OCP loop 1202 has a dynamic threshold that may change the control signals to the bias circuits 174, 214. That is, if any of the operating parameters 1204 change, the threshold current that triggers the OCP circuitry may change. Thus, as illustrated in graph 1100, if the supply voltage (Vcc) goes up, the threshold current may go down. Similarly, if the temperature goes up, the threshold current may go down; if the frequency goes up, the threshold current may go down; if the power levels go up, the threshold current may go down; if the modulation scheme changes (e.g., 2G, 3G, 4G, 5G), the threshold current may change; and if the VSWR changes, the threshold current may go down. As noted, the threshold current may also change as a combination of some or all of these operating parameters, and this list is not intended to be exhaustive, and other operating parameters may be considered. As still another possibility, the threshold may not only be adjusted but also the action taken may change. For example, if the VSWR exceeds a threshold, the power amplifier 208 may be shut down completely on the theory that a dropped call or degraded call is preferable to a damaged power amplifier.

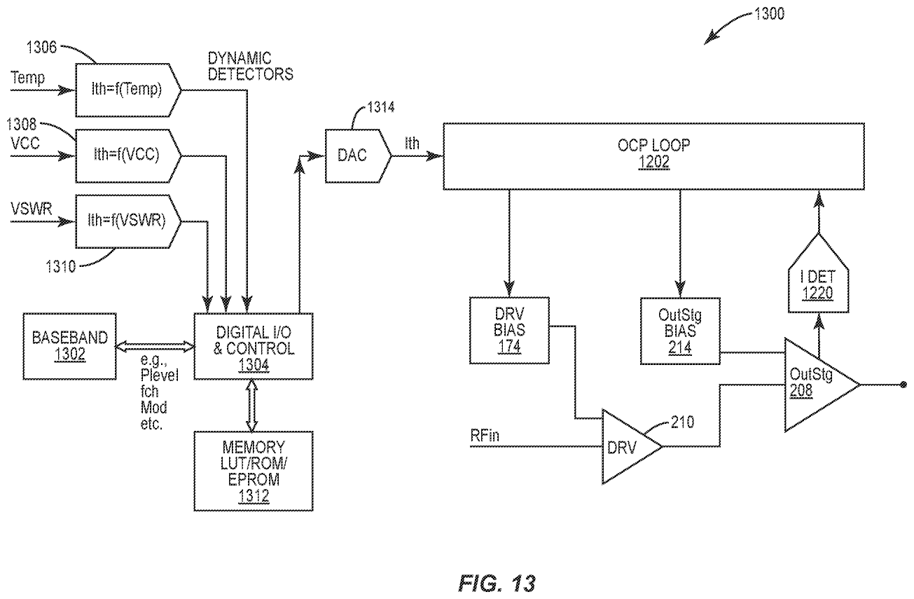

FIG. 13 provides a schematic diagram of a power amplifier circuit 1300 that more explicitly dynamically changes the threshold based on operating parameters. Thus, the power amplifier circuit 1300 may include a BBP 1302 that provides information to a control circuit 1304, such as power level, frequency, and/or modulation scheme. Sensors (not shown) may provide information regarding temperature (input 1306), supply voltage (input 1308), and/or VSWR (input 1310). Based on these inputs, the control circuit 1304 may use values stored in a memory 1312 (e.g., read-only memory (ROM), electronically programmable ROM (EPROM), or the like), which may include a look-up table or the like. The value from the control circuit 1304 may be converted by a DAC 1314 and provided to the OCP loop 1202. Alternatively, a voltage may be provided by the control circuit 1304 and converted to Ith by passing through a resistor (not shown).

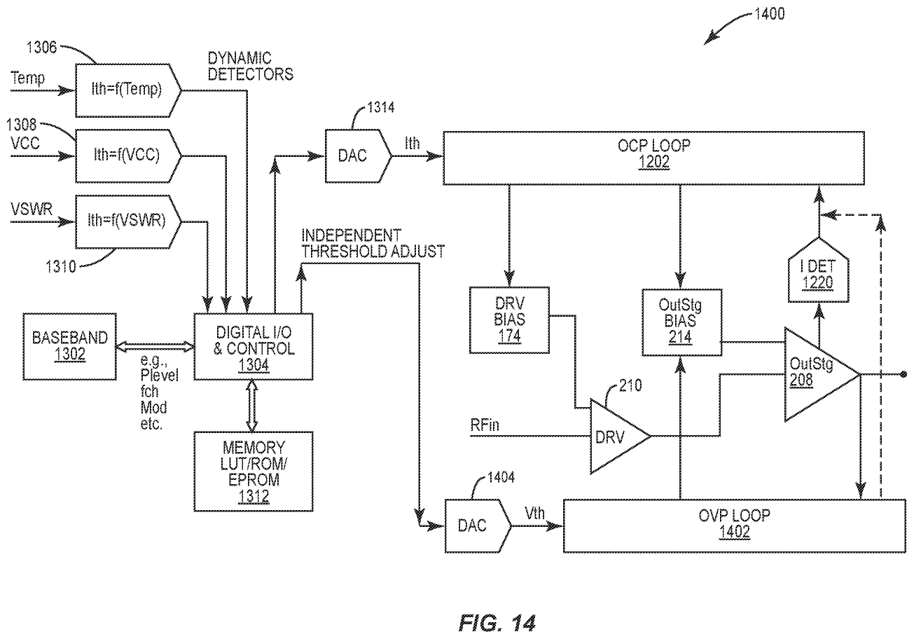

As discussed above, the OCP loop 1202 may be combined with an OVP loop 1402, as shown in the power amplifier circuit 1400 of FIG. 14. It should be appreciated that, as discussed above, the OVP loop 1402 may be subordinated to the OCP loop 1202 or independent therefrom. The voltage threshold (Vth) may be dynamically adjusted by the control circuit 1304 based on the any or all of the inputs and information. The voltage threshold Vth may be provided in analog form through a DAC 1404.

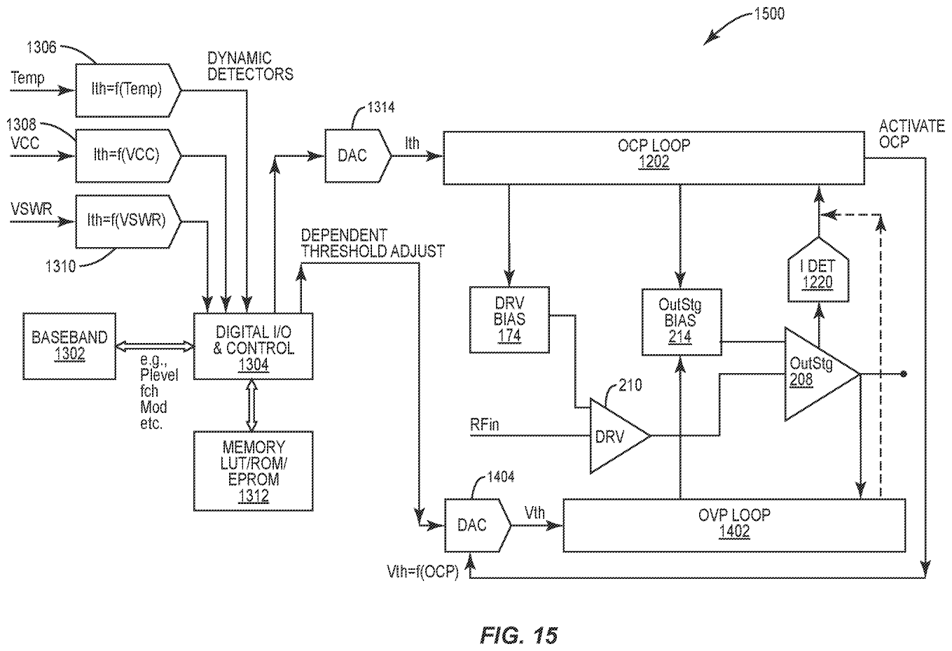

FIG. 15 provides a schematic diagram of a power amplifier circuit 1500 where the OCP loop 1202 controls the threshold of the OVP loop 1402 by providing a signal 1502 to the DAC 1404 that sets Vth. There may be a comparator that takes the lower Vth value between the Vth set by the control circuit 1304 and the OCP loop 1202. Thus, if the OCP loop 1202 is activated by some over current condition (regardless of whether Ith has been adjusted), the signal from the OCP loop 1202 may cause Vth to be adjusted dynamically with the understanding that the operating parameters, which may have caused Ith to change and OCP loop 1202 to begin throttling operation may also be adjusting Vth.

While OVP loops are specifically referenced relative to the OCP loops of the present disclosure, there may be other protection loops that are used independently or subordinated to the OCP. For example, an over-temperature loop or over-power loop may also be present. It should also be appreciated that the adjustments to the threshold could be a single-step function type adjustment or a multi-step reduction depending on the various operating parameters.

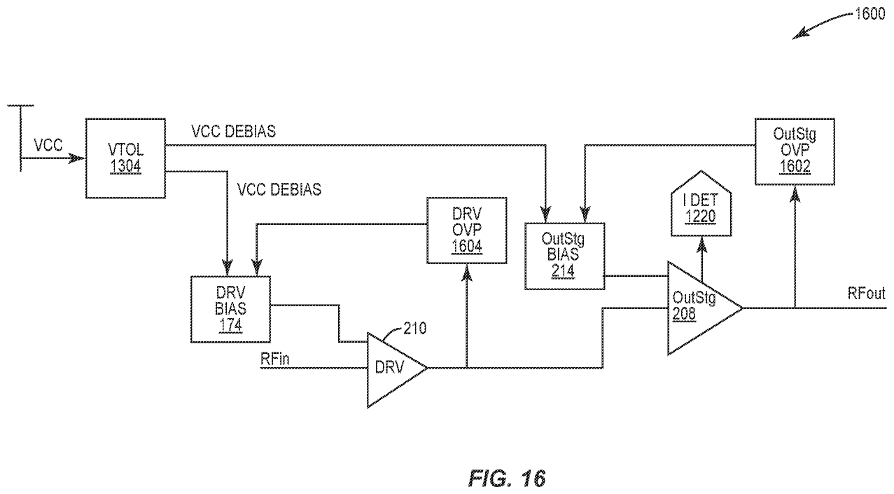

There may also be situations where it is appropriate to have multiple protection loops of the same sort. For example, it may be possible to have multiple OVP loops, as shown in the power amplifier circuit 1600 of FIG. 16. The OCP loop is not shown, although the detector 1220 is shown. A first OVP loop 1602 may be associated with the output power amplifier 208 and may adjust the bias circuit 214. A second OVP loop 1604 may be associated with the driver amplifier stage 210 and may adjust the driver bias circuit 174. The bias circuits 174, 214 may also be directly controlled by the control circuit 1304.

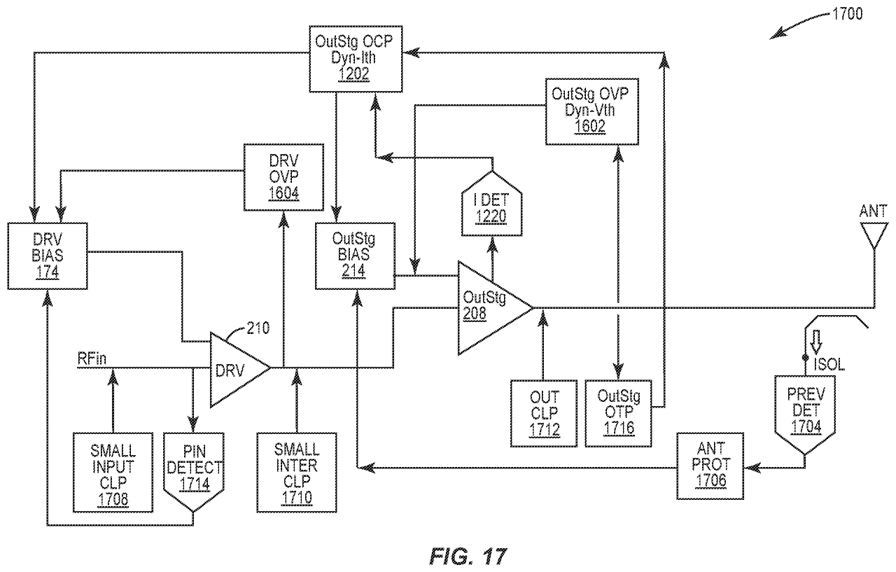

FIG. 17 provides a schematic diagram of a power amplifier circuit 1700 that combines many of the features discussed herein. Thus, the power amplifier circuit 1700 may detect power at an antenna 1702 with a power detector 1704 for an antenna power protection circuit 1706. The antenna power protection circuit 1704 may report to a control circuit (not shown) or directly debias the bias circuit 214. Clamps 1708, 1710, and 1712 may provide hard clamp limits on power levels before the driver amplifier stage 210, between the driver amplifier stage 210 and output amplifier 208 and at the output of the output amplifier 208. A power detector 1714 may be coupled to the input of the driver amplifier stage 210 and control the driver bias circuit 174. An overtemperature loop 1716 may provide input to the OCP loop 1202 or work independently as needed or desired.

Those skilled in the art will recognize improvements and modifications to the preferred embodiments of the present disclosure. All such improvements and modifications are considered within the scope of the concepts disclosed herein and the claims that follow.

1. A power amplifier circuit, comprising:
a power amplifier comprising an output stage configured to provide an amplified output signal;
a bias circuit coupled to the output stage and configured to provide a bias signal to the output stage;
a regulator circuit coupled to the bias circuit and configured to provide a regulator signal to the bias circuit;
a current detector circuit coupled to the power amplifier, the current detector circuit configured to detect a current associated with the regulator signal and further configured to provide an overcurrent protection (OCP) signal when the current is above a threshold; and
a control circuit configured to receive one or more operating parameters and dynamically set the threshold based on the one or more operating parameters.

2. The power amplifier circuit of claim 1, wherein at least one of the one or more operating parameters comprises a supply voltage.

3. The power amplifier circuit of claim 1, wherein at least one of the one or more operating parameters comprises a voltage standing wave ratio (VSWR).

4. The power amplifier circuit of claim 1, wherein at least one of the one or more operating parameters comprises a modulation scheme.

5. The power amplifier circuit of claim 1, further comprising an overvoltage protection circuit (OVP) configured to measure a voltage and provide an OVP signal when the voltage exceeds a voltage threshold.

6. The power amplifier circuit of claim 5, wherein the control circuit is further configured to set the voltage threshold on the one or more operating parameters.

7. The power amplifier circuit of claim 1, wherein the power amplifier further comprises a driver stage.

8. The power amplifier circuit of claim 2, wherein the control circuit is configured to lower the threshold when the supply voltage increases.

9. The power amplifier circuit of claim 1, wherein the control circuit is configured to change the threshold with a multi-step function.

10. The power amplifier circuit of claim 1, wherein the control circuit is configured to receive information relating to different ones of the one or more operating parameters from local sensors and a baseband processor.

11. A power amplifier circuit, comprising:
a power amplifier comprising an output stage configured to provide an amplified output signal;
a voltage detector circuit coupled to the power amplifier, the voltage detector circuit configured to detect a voltage level of the output signal and further configured to provide an overvoltage protection (OVP) signal when the voltage level exceeds a threshold; and
a control circuit configured to receive one or more operating parameters and dynamically set the threshold based on the one or more operating parameters.

12. The power amplifier circuit of claim 11, wherein at least one of the one or more operating parameters comprises a supply voltage.

13. The power amplifier circuit of claim 11, wherein at least one of the one or more operating parameters comprises a voltage standing wave ratio (VSWR).

14. The power amplifier circuit of claim 11, wherein at least one of the one or more operating parameters comprises a modulation scheme.

15. The power amplifier circuit of claim 11, wherein the power amplifier further comprises a driver stage.

16. The power amplifier circuit of claim 15, further comprising a second voltage detector circuit coupled to the driver stage and configured to generate a second OVP signal when a driver voltage exceeds a driver voltage exceeds a driver voltage threshold.

17. The power amplifier circuit of claim 12, wherein the control circuit is configured to lower the threshold when the supply voltage increases.

18. The power amplifier circuit of claim 11, wherein the control circuit is configured to change the threshold with a multi-step function.

19. A power amplifier circuit comprising:
a power amplifier comprising an output stage configured to provide an amplified output signal;
a current detector circuit coupled to the power amplifier, the current detector circuit configured to detect a current associated with the power amplifier and further configured to provide an overcurrent protection (OCP) signal when the current is above a dynamic threshold set by a control circuit based on one or more operating parameters; and
a voltage detection circuit coupled to the output stage, the voltage detection circuit configured to:
generate an overvoltage protection (OVP) signal when the voltage detection circuit detects a first voltage exceeding a first over-voltage threshold; and
generate the OVP signal when the current detector circuit indicates an overcurrent condition and the voltage detection circuit detects a second voltage exceeding a second over-voltage threshold lower than the first over-voltage threshold.
